(19) United States
(12) Patent Application Publication
(10) Pub. No.: US 2026/0140215 A1
(43) Pub. Date: May 21, 2026

(54) SYSTEM AND METHOD FOR MULTIPHOTON PARALLEL TRANSMIT EXCITATION FOR MRI

(71) Applicant: The General Hospital Corporation, Boston, MA (US)

(72) Inventors: Lawrence L. Wald, Cambridge, MA (US); John Drago, Cambridge, MA (US); Bastien Guerin, Somerville, MA (US)

(21) Appl. No.: 19/120,194

(22) PCT Filed: Oct. 12, 2023
(86) PCT No.: PCT/US2023/076709

§ 371 Date: Apr. 10, 2025

Related U.S. Application Data
(60) Provisional application No. 63/415,586, filed on Oct. 12, 2022.

(51) Int. Cl. G01R 33/56; G01R 33/34; G01R 33/3875

(52) U.S. Cl. CPC G01R 33/5608; G01R 33/34076; G01R 33/3875

(57) ABSTRACT

A method for generating a magnetic resonance image of a subject using a magnetic resonance imaging (MRI) system includes receiving, using the MRI system, at least one parameter for a multiphoton parallel transmit excitation comprising a multiphoton excitation pulse configured to correct spatial inhomogeneities and performing, using the MRI system, a pulse sequence comprising the multiphoton parallel transmit excitation to acquire data from the subject. The multi photon excitation pulse of the multi photon parallel transmit excitation is performed using a radio frequency (RF) coil and a set of one or more shim coils of the MRI system. The method further includes generating, using a processor, an image of the subject using the acquired MR data. In some embodiments, the multiphoton excitation pulse includes an off-resonance RF excitation pulse performed using the RF coil and a plurality of low-frequency excitation pulses performed using the set of one or more shim coils. The plurality of low-frequency excitation pulses are performed simultaneously with the off-resonance RF excitation pulse.

### CROSS-REFERENCE TO RELATED APPLICATIONS

This application is based on, claims priority to, and incorporates herein by reference in its entirety U.S. Ser. No. 63/415,586 filed Oct. 12, 2022, and entitled “Multi-Photon Parallel Transmit For MRI Excitation.”

### STATEMENT REGARDING FEDERALLY SPONSORED RESEARCH OR DEVELOPMENT

This invention was made with government support under award number 5R01EB006847-12 awarded by the National Institutes of Health. The government has certain rights in the invention.

### FIELD

The present disclosure relates generally to magnetic resonance imaging and, more particularly, to systems and methods for multiphoton parallel transmit excitation for the acquisition of MR images.

### BACKGROUND

Magnetic Resonance Imaging (MRI) is a well-known tomographic imaging modality which has already substantially impacted medical practice. MRI has become a staple of anatomic, physiologic, and functional imaging, and is routinely used in clinical medical practice. Typical clinical MRI scanners operate with a main external magnetic field strength, B₀, of 1.5T or 3T. Over the past 15 years, there has been a push towards higher field strengths, as the signal-to-noise ratio in MRI is approximately proportional to the field strength, B₀. Pushing the magnetic field to higher and higher levels (up to 7T for clinical scanners) has increased what MRI can see through improved sensitivity and spatial resolution but has also generated some additional problems stemming from the wavelength of the radiofrequency (RF) waves needed for excitation. For high field MRI RF excitation, the image intensity and contrast are modulated across the body in complex ways (the so-called “flip angle inhomogeneity” problem). Parallel transmit methods employing and optimizing an array of transmit antenna were introduced to address this problem. In parallel transmit methods, multiple, individually driven waveforms are sent to the transmit coils. However, parallel transmit methods add significantly to the scanner cost and complexity and introduce a range of concerns about local tissue heating (the so-called “local-SAR” problem).

It would be desirable to provide systems and methods for MRI excitation that address both the problems of convention excitation and conventional parallel transmit excitation such as flip angle inhomogeneity and local tissue heating.

### SUMMARY

In accordance with an embodiment, a method for generating a magnetic resonance image of a subject using a magnetic resonance imaging (MRI) system includes receiving, using the MRI system, at least one parameter for a multiphoton parallel transmit excitation comprising a multiphoton excitation pulse configured to correct spatial inhomogeneities and performing, using the MRI system, a pulse sequence comprising the multiphoton parallel transmit excitation to acquire data from the subject. The multiphoton excitation pulse of the multiphoton parallel transmit excitation is performed using a radio frequency (RF) coil and a set of one or more shim coils of the MRI system. The method further includes generating, using a processor, an image of the subject using the acquired MR data.

In accordance with another embodiment, a magnetic resonance imaging (MRI) system includes a magnet system configured to generate a polarizing magnetic field about at least a portion of a subject, a gradient system including a plurality of gradient coils configured to apply at least one magnetic gradient field to the polarizing magnetic field, a radio frequency (RF) system including at least one RF coil and configured to apply an RF excitation field to the subject and to receive magnetic resonance signals from the subject using the at least one RF coil, a set of one or more shim coils, and a computer system. The computer system is programmed to receive at least one parameter for a multiphoton parallel transmit excitation comprising a multiphoton excitation pulse configured to correct spatial inhomogeneities, and direct the plurality of magnetic gradient coils, the RF coil, and the set of one or more shim coils to perform a pulse sequence comprising the multiphoton parallel transmit excitation to acquire data from the subject. The multiphoton excitation pulse of the multiphoton parallel transmit excitation is performed using the RF coil and the set of one or more shim coils.

### BRIEF DESCRIPTION OF THE DRAWINGS

The present disclosure will hereafter be described with reference to the accompanying drawings, wherein like reference numerals denote like elements.

FIG. 1 is a block diagram of an example magnetic resonance imaging (MRI) system in accordance with an embodiment;

FIG. 2 is a block diagram of an example magnet assembly including a set of one or more shim coils in accordance with an embodiment:

FIGS. 3A and 3B illustrate example shim coil arrays in accordance with an embodiment:

FIG. 4 illustrates an example multiphoton parallel transmit (MP-pTx) excitation in accordance with an embodiment;

FIG. 5 illustrates a method for generating a magnetic resonance image of a subject using an MP-pTx excitation in accordance with an embodiment; and

FIG. 6 illustrates example magnetization trajectories for two locations in a subject in accordance with an embodiment.

### DETAILED DESCRIPTION

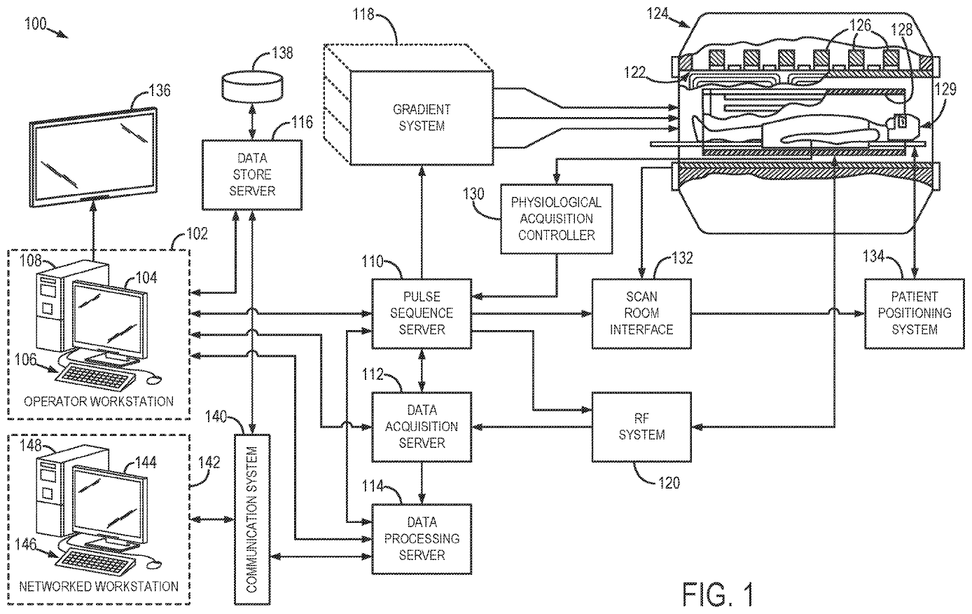

FIG. 1 shows an example of an MRI system 100 that may be used to perform the methods described herein. The MRI system 100 includes an operator workstation 102, which may include a display 104, one or more input devices 106 (e.g., a keyboard and mouse), and a processor 108. The processor 108 may include a commercially available programmable machine running a commercially available operating system. The operator workstation 102 provides the operator interface that facilitates entering scan parameters (e.g., a scan prescription) into the MRI system 100. The operator workstation 102 may be coupled to different servers, including, for example, a pulse sequence server 110, a data acquisition server 112, a data processing server 114, and a data store server 116. The operator workstation 102 and the servers 110, 112, 114, and 116 may be connected via a communication system 140, which may include any suitable network connection, whether wired, wireless, or a combination of both.

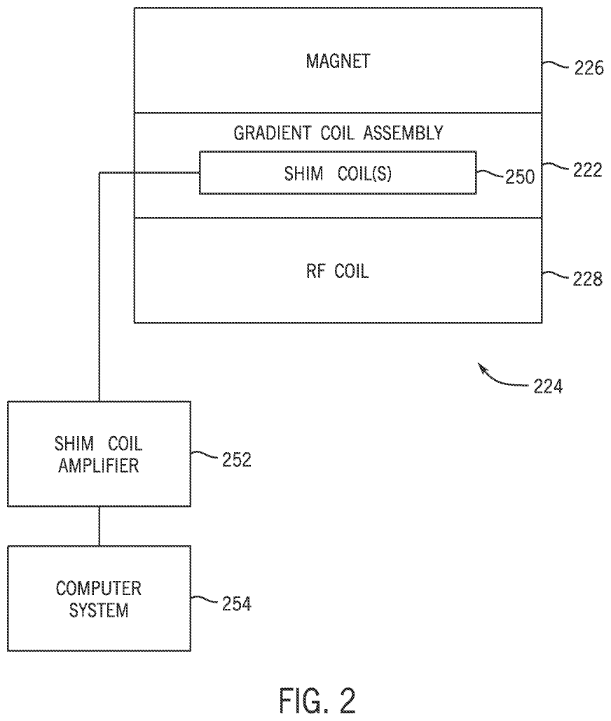

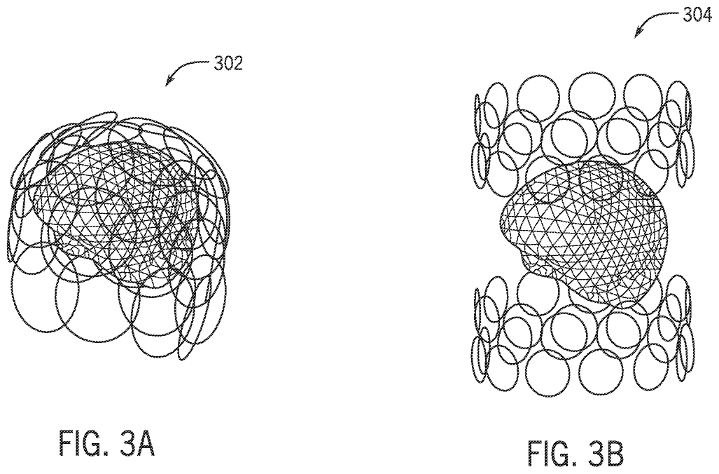

The pulse sequence server 110 functions in response to instructions provided by the operator workstation 102 to operate a gradient system 118 and a radiofrequency (“RF”) system 120. Gradient waveforms for performing a prescribed scan are produced and applied to the gradient system 118, which excites gradient coils in an assembly 122 to produce the magnetic field gradients Gₓ, G_{y}, and G_{z} that are used for spatially encoding magnetic resonance signals. The gradient coil assembly 122 forms part of a magnet assembly 124 that includes a polarizing magnet 126 and one or more RF coils (e.g., a whole-body RF coil 128) and/or a local coil, such as a head coil 129. In some embodiments, the one or more RF coils can be driven independently or with a fixed amplitude/phase relationship. In some embodiments, the whole-body RF coil 128 and/or local coil (e.g., head coil 129) may be a birdcage coil. In some embodiments, the magnet assembly 124 may also include one or more shim coils (not shown), for example, a shim coil array. In some embodiments, the shim coil(s) may be used to, for example, compensate for or remove inhomogeneities from the main magnetic field. B₀, generated by the polarizing magnet 126. As discussed further below with respect to FIG. 2, the shim coil(s) (e.g., a shim coil array) may be located, for example, inside the gradient coil assembly 122 or at other locations in the magnet assembly 124. In some embodiments, shim coil(s) may be incorporated in the structure of a local coil, for example, head coil 129, as discussed below with respect to FIGS. 3A and 3B.

RF waveforms are applied by the RF system 120 to the RF coil 128, or a separate local coil (e.g., the head coil 129), to perform the prescribed magnetic resonance pulse sequence. Responsive magnetic resonance signals detected by the RF coil 128, or a separate and possibly distinct local coil (e.g., the head coil 129), are received by the RF system 120. The responsive magnetic resonance signals may be amplified, demodulated, filtered, and digitized under direction of commands produced by the pulse sequence server 110. The RF system 120 includes an RF transmitter for producing a wide variety of RF pulses used in MRI pulse sequences. The RF transmitter is responsive to the prescribed scan and direction from the pulse sequence server 110 to produce RF pulses of the desired frequency, phase, and pulse amplitude waveform. The generated RF pulses may be applied to the whole-body RF coil 128 or to one or more local coils or coil arrays, such as, for example, the head coil 129.

The RF system 120 also includes one or more RF receiver channels. Each RF receiver channel includes an RF preamplifier that amplifies the magnetic resonance signal received by the coil 128,129 to which it is connected, and a detector that detects and digitizes the I and Q quadrature components of the received magnetic resonance signal. The magnitude of the received magnetic resonance signal may, therefore, be determined at any sampled point by the square root of the sum of the squares of the I and Q components:

$$M = \qquad ( 1 )$$

and the phase of the received magnetic resonance signal may also be determined according to the following relationship:

$$φ = {tan}^{- 1} \qquad ( 2 )$$

The pulse sequence server 110 may receive patient data from a physiological acquisition controller 130. By way of example, the physiological acquisition controller 130 may receive signals from a number of different sensors connected to the patient, such as electrocardiograph (“ECG”) signals from electrodes, or respiratory signals from a respiratory bellows or other respiratory monitoring device. Such signals are typically used by the pulse sequence server 110 to synchronize, or “gate,” the performance of the scan with the subject's heartbeat or respiration.

The pulse sequence server 110 may also connect to a scan room interface circuit 132 that receives signals from various sensors associated with the condition of the patient and the magnet system. Through the scan room interface circuit 132, a patient positioning system 134 can receive commands to move the patient to desired positions during the scan.

The digitized magnetic resonance signal samples produced by the RF system 120 are received by the data acquisition server 112. The data acquisition server 112 operates in response to instructions downloaded from the operator workstation 102 to receive the real-time magnetic resonance data and provide buffer storage, such that no data is lost by data overrun. In some scans, the data acquisition server 112 passes the acquired magnetic resonance data to the data processor server 114. In scans that require information derived from acquired magnetic resonance data to control the further performance of the scan, the data acquisition server 112 may be programmed to produce such information and convey it to the pulse sequence server 110. For example, during pre-scans, magnetic resonance data may be acquired and used to calibrate the pulse sequence performed by the pulse sequence server 110. As another example, navigator signals may be acquired and used to adjust the operating parameters of the RF system 120 or the gradient system 118, or to control the view order in which k-space is sampled. In still another example, the data acquisition server 112 may also process magnetic resonance signals used to detect the arrival of a contrast agent in a magnetic resonance angiography (“MRA”) scan. For example, the data acquisition server 112 may acquire magnetic resonance data and process it in real-time to produce information that is used to control the scan.

The data processing server 114 receives magnetic resonance data from the data acquisition server 112 and processes it in accordance with instructions downloaded from the operator workstation 102. Such processing may include, for example, reconstructing two-dimensional or three-dimensional images by performing a Fourier transformation of raw k-space data, performing other image reconstruction algorithms (e.g., iterative or back-projection reconstruction algorithms), applying filters to raw k-space data or to reconstructed images, generating functional magnetic resonance images, or calculating motion or flow images.

Images reconstructed by the data processing server 114 are conveyed back to the operator workstation 102 for storage. Real-time images may be stored in a data base memory cache (not shown in FIG. 1), from which they may be output to operator display 104 or a display 136. Batch mode images or selected real time images may be stored in a host database on disc storage 138. When such images have been reconstructed and transferred to storage, the data processing server 114 notifies the data store server 116 on the operator workstation 102. The operator workstation 102 may be used by an operator to archive the images, produce films, or send the images via a network to other facilities.

The MRI system 100 may also include one or more networked workstations 142. By way of example, a networked workstation 142 may include a display 144, one or more input devices 146 (e.g., a keyboard and mouse), and a processor 148. The networked workstation 142 may be located within the same facility as the operator workstation 102, or in a different facility, such as a different healthcare institution or clinic.

The networked workstation 142 may gain remote access to the data processing server 114 or data store server 116 via the communication system 140. Accordingly, multiple networked workstations 142 may have access to the data processing server 114 and the data store server 116. In this manner, magnetic resonance data, reconstructed images, or other data may exchanged between the data processing server 114 or the data store server 116 and the networked workstations 142, such that the data or images may be remotely processed by a networked workstation 142. This data may be exchanged in any suitable format, such as in accordance with the transmission control protocol (TCP), the internet protocol (IP), or other known or suitable protocols.

As mentioned above, magnet assembly 124 may also include one or more shim coils, for example, a single shim coil or a shim coil array. In some embodiments, an optimized coil winding (or set of optimized coil windings) may constitute a shim coil. In some embodiments, the shim coil(s) may be positioned at a location within the magnet assembly 124 or the shim coil(s) may be incorporated in a local coil, for example, head coil 129. FIG. 2 is a block diagram of an example magnet assembly including a set of one or more shim coils in accordance with an embodiment. In FIG. 2, a magnet assembly 224 (e.g., magnet assembly 124 of MRI system 100 shown in FIG. 1) can include a polarizing magnet 126, a gradient coil assembly 222, and one or more RF coil(s) 228 (e.g., a whole body RF coil 128 shown in FIG. 1). As mentioned above, in some embodiments, the one or more RF coils 228 can be driven independently or with a fixed amplitude/phase relationship. Various other elements of a magnet assembly are omitted from FIG. 2 for clarity. Magnet assembly 224 can also include a set of one or more shim coils 250 (e.g., a single shim coil, a shim coil array, etc.). In some embodiments, shim coil(s) 250 may be resistive shim coils. In the embodiment shown in FIG. 2, shin coil(s) (e.g., a single shim coil, shim coil array, etc.) 250 can be located inside the gradient coil assembly 122. For example, the shim coil(s) 250 may be located in a volume or space between inner and outer gradient coils (not shown) in the gradient coil assembly 222. In some embodiments, the shim coil(s) 250 are full-size shim coils and, accordingly, may be on a cylindrical former of similar length as the gradient coil assembly 222. While the shim coil(s) 250 are shown within the gradient coil assembly 222 in FIG. 2, it should be understood that in other embodiments, the shim coil(s) 250 may be positioned at other locations in the magnet assembly 224. In some embodiments, the shim coil(s) 250 may be mounted to another component of the magnet assembly 224, for example, the RF coil 228.

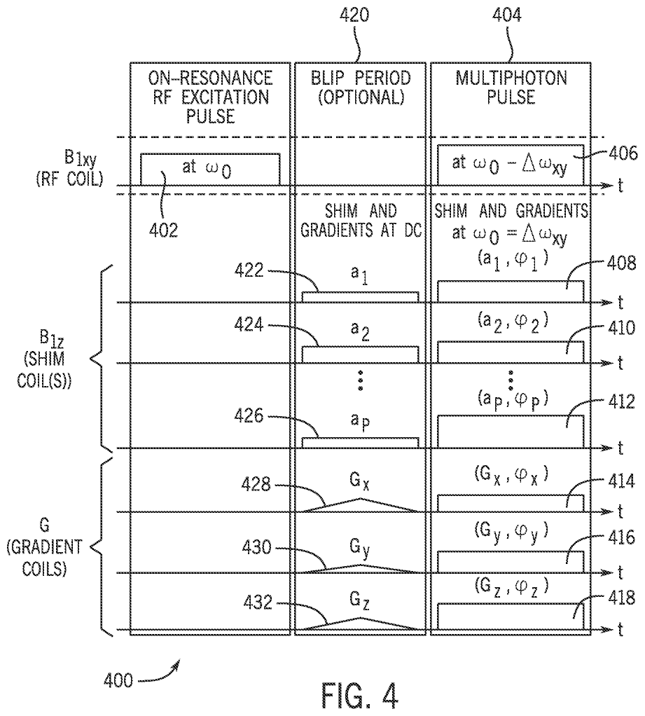

Shim coil(s) 250 (e.g., a single shim coil, a shim coil array, etc.) may be used to, for example, compensate for or remove inhomogeneities from the magnetic field. B₀, generated by the magnet 126. Typically, a current is passed through the shim coil(s) 250 to create the corrective magnetic fields. Shim coil(s) 250 may be powered by an amplifier 252 and waveforms generated by amplifier 252 may be controlled by a computer system 254 (e.g., operator workstation 102 or pulse sequence server 110 shown in FIG. 1). In some embodiments, the computer system 254 and amplifier 252 are configured to control the current supplied to the shim coil(s) 250. In particular, during a scan operation, the shim coil(s) 250 can be energized to provide real-time compensation of magnetic field distortions. The current through the shim coil(s) 250 may be adjusted or regulated to provide the appropriate corrective field. In some embodiments, the shim coil(s) 250 (e.g., a single shim coil, a shim coil array, etc.) may advantageously be used to provide a plurality of z-directed, low-frequency fields for multiphoton parallel transmit excitation, as described further below with respect to FIG. 4-6. In some embodiments, an optimized coil winding (or set of optimized coil windings) may constitute a shim coil and be used to provide spatially targeted low-frequency fields.

As mentioned above, in some embodiments, shim coil(s) may be incorporated in a local coil, for example, head coil 129 (shown in FIG. 1). FIGS. 3A and 3B illustrate example shim coil arrays in accordance with an embodiment. FIG. 3A illustrates an example 32-channel shim coil array 302. FIG. 3B illustrates an example 48-channel shim coil array 304. Each of the shim coil arrays 302 and 304 include a plurality of individual shim coils. Shim coil array 302 and shim coil array 304 may be a similar shape and length as a head coil (e.g., head coil 129). As discussed above with respect to FIG. 2, shim coil arrays 302, 304 may be coupled to an amplifier 252 and computer system 254 that can be configured to control the current supplied to the shim coil arrays 302, 304. While FIGS. 2, 3A and 3B illustrate a head coil 129 and shim coil arrays 302, 304 for a head coil, respectively, it should be understood that shim coil(s) (e.g., a single shim coil, shim coil arrays, etc.) may be incorporated in the structure of other types of specialty or local coils. As mentioned above, in some embodiments, an optimized coil winding (or set of optimized coil windings) may constitute a shim coil.

The present disclosure describes systems and methods for multiphoton parallel transmit (MP-pTx) excitation for MRI. The disclosed MP-pTx excitation may be used in a pulse sequence performed by an MRI system to acquire magnetic resonance (MR) data from a subject and the acquired MR data may be used, for example, to generate an image of the subject. The disclosed MP-pTx excitation can be used to control the spatial profile of excitation for MRI. In some embodiments, the MP-pTx excitation includes an on-resonance RF excitation pulse followed by a multiphoton excitation pulse. In some embodiments, the on-resonance RF excitation pulse may be generated or performed using an RF coil such as, for example, a birdcage coil. In some embodiments, the multiphoton excitation pulse may be applied before an on-resonance RF excitation pulse, the multiphoton pulse may be used alone, or a combination of on-resonance RF excitation pulses and multiphoton excitation pulses may be used. In some embodiments, an off-resonance RF excitation pulse may be used before or after the multiphoton excitation pulse. In some embodiments, the RF excitation pulse may have both on-resonant and off-resonant frequency components simultaneously.

Advantageously, the multiphoton excitation pulse is configured to utilize the multiphoton excitation phenomenon and may be used to, for example, correct spatial inhomogeneities of the on-resonance RF excitation pulse. In some embodiments, the multiphoton excitation pulse includes an off-resonance RF excitation pulse and a plurality of low-frequency excitation pulses applied simultaneously with the off-resonance RF excitation pulse. Accordingly, the off-resonance RF excitation pulse may be supplemented with the plurality of low frequency excitation pulses. In some embodiments, the off-resonance RF excitation pulse may be generated or performed using an RF coil such as, for example, a birdcage coil. Advantageously, in some embodiments, the plurality of low frequency excitation pulses may be generated or performed using a set of one or more shim coils, for example, a single shim coil or a shim coil array. In some embodiments, the amplitudes and phase of the various pulses generated by the RF coil and the set of one or more shim coils may be modulated through time.

In some embodiments, in the MP-pTx excitation, the on-resonance RF excitation pulse may be employed to efficiently complete most of the desired excitation, and then may be followed by the multiphoton excitation pulse which may be configured to utilize the degrees of freedom present in the low-frequency shim coil or coils to “fix” the spatial inhomogeneities, resulting in a more uniform excitation achieved with a single conventional high-frequency excitation and without the specific absorption rate (SAR) concerns of conventional parallel transmit techniques. The disclosed multiphoton excitation pulse can advantageously utilize the multiphoton excitation phenomena for excitation uniformity mitigation in MRI. In addition, the disclosed multiphoton excitation pulse may also be used to achieve other target (e.g., as desired by a user or operator of the MRI system) spatial excitation profiles or patterns.

In some embodiments, to address the spatial flip angle inhomogeneity problem, the disclosed system and method for MP-pTx excitation can use a conventional birdcage transmit coil (a single high-frequency channel) to apply an off-resonance B₁ field (e.g., via an off-resonance RF excitation pulse) such as, for example, a transverse a B₁⁺ RF field, and can use a set of one or more low-frequency z-directed shim coils (e.g., a single low frequency shim coil, a low-frequency shim coil array, etc.) to apply low frequency z-directed fields (B_{1z}) which supplement the off-resonance B₁ field. Using the low-frequency coil(s) in the set of one or more shim cols (e.g., a single shim coil, a shim coil array, etc.) to apply the low frequency z-directed B_{1z} fields (e.g., via a plurality of low frequency excitation pulses) can help lower cost and significantly simplifies SAR management, since SAR is negligible at low frequencies, independent of how the shim coil array is energized. In some embodiments, the disclosed MP-pTx excitation can create a more homogeneous excitation at high field strengths. In some embodiments, the set of one or more shim coils (e.g., a single shim coil, a shim coil array, etc.) may be an existing piece of hardware on the MRI system used to, for example, correct main magnetic field (B₀) inhomogeneities. The existing shim coil(s) on an MRI system can also advantageously provide a low-cost way to apply the additional low-frequency oscillatory fields of the multiphoton excitation pulse with many degrees of freedom, i.e., the amplitudes and phases of the low frequency oscillatory fields. The disclosed system and methods for MP-pTx excitation can address the excitation (flip angle) inhomogeneity issue without the expense of added high frequency power channels or concerns about increasing local SAR above conventional single-channel excitations. In some embodiments, the set of one or more shim coils can include a plurality of shim coils (e.g., a shim coil array) that are configured to provide a B_{1z} field pattern needed to create a target excitation pattern (e.g., a homogeneous excitation pattern). In some embodiments, the set of one or more shim coils may include a single shim coil with a set of windings (or winding patterns) calculated to provide a B_{1z} field pattern needed to create a target excitation pattern (e.g., a homogeneous excitation pattern (or profile)). In some embodiments, the winding patterns of one or more of the shim coils can also be configured to achieve the needed spatial pattern to complete the excitation and achieve the target excitation profile (or pattern).

Advantageously, the disclosed systems and method for MP-pTx excitation provide improvements over conventional excitation and conventional parallel transmit excitation in cost, simplicity and in that it has considerably improved energy deposition (specific absorption rate (SAR)) constraints. In some embodiments, the disclosed MP-pTx excitation methods can be used to solve the flip angle inhomogeneity problem with a vastly cheaper hardware configuration and no SAR concerns. The set of one or more shim coils (e.g., a single shim coil, a shim coil array, etc.) can provide a low-cost way to apply additional, low-frequency oscillatory fields with many degrees of freedom (e.g., the amplitudes and phases of these fields). In some embodiments, the SAR energy deposited can be reduced by nearly 100 fold since only low-frequency excitation is used in the parallel array.

FIG. 4 illustrates an example multiphoton parallel transmit (MP-pTx) excitation in accordance with an embodiment. In FIG. 4, the multiphoton parallel transmit (MP-pTx) excitation 400 includes an on-resonance RF excitation pulses 402 followed by a multiphoton excitation pulse (or multiphoton pulse) 404. In some embodiments, the MP-pTx excitation 400 may also include an optional blip period 420, as discussed further below. In some embodiments, the MP-pTx excitation may be used in a pulse sequence employed by an MRI system (e.g., MRI system 100 shown in FIG. 1) to acquire MR data for various applications such as, for example, body imaging or head imaging. The on-resonance RF excitation pulse 402 may be applied using an RF coil (e.g., RF coil 128 or local coil 129) of an MRI system. In some embodiments, the on-resonance RF excitation pulse 402 may be circularly polarized and applied at the Larmor frequency (ω₀) using a single-channel, high frequency RF coil such as, for example, a birdcage coil. The on-resonance RF excitation 402 can generate an efficient, but spatially non-uniform excitation (e.g., transverse magnetic field B_{1xy}).

The on-resonance RF excitation pulse 402 may then be followed by a multiphoton excitation pulse (or multiphoton pulse) 404. Multiphoton excitation pulse 404 can include an off-resonance RF excitation pulse 406 and a plurality of low frequency excitation pulses 408, 410, 412. The off-resonance RF excitation pulse 406 may be applied using an RF coil (e.g., RF coil 128 or local coil 129) of an MRI system. In some embodiments, the off-resonance RF excitation pulse 406 may be circularly polarized and applied at a frequency (ω₀−Δω_{xy}) off resonance from the Larmor frequency by an offset frequency (Δω_{xy}) using a single-channel, high frequency RF coil such as, for example, a birdcage coil. The off-resonance RF excitation pulse 406 can generate a spatially-dependent transverse magnetization, B_{1xy}. The plurality of low frequency excitation pulses can include P total pulses (e.g., first pulse 408, second pulse 410, . . . . Pth pulse 412) and can be applied or performed simultaneously with the off-resonance excitation pulse 406. The plurality of low frequency excitation pulses 408, 410, 412 can advantageously be applied using a set of one or more shim coils (e.g., shim coil(s) 250, 302, 304 shown in FIGS. 2, 3A and 3B, respectively). In some embodiments, the set of one or more shim coils include a plurality of shim coils and each of the plurality of low frequency excitation pulses 408, 410, 412 can be applied using a different shim coil in the plurality of shim cols. In some embodiments, the set of one or more shim coils may include a single shim coil with a set of windings calculated to provide the plurality of low frequency excitation pulses 408, 410, 412. In some embodiments, each of the plurality of low frequency excitation pulses 408, 410, 412 are applied at the offset frequency, Δω_{xy}. In some embodiments, the low frequency excitation pulses may operate at a frequency in the tens of kilohertz, where minimal energy is absorbed by the body. Each low frequency excitation pulse 408, 410, 412 can generate a z-directed oscillating field, B_{1z}_{ₚ}. In the multiphoton excitation pulse 404, the sum of the individual fields, B_{1z}_{ₚ}, generated by the low frequency excitation pulses 408, 410, 412 can supply the small amount of additional energy needed to complete energy conservation in the spin transition. i.e., convert z-axis magnetization into magnetization in the xy-plane. In some embodiments, various parameters of each low frequency excitation pulse (or field), for example, the amplitude (aₚ), phase (φₚ), pulse duration, waveform, etc., may be selected to, for example, optimize the uniformity of the overall excitation or to perform other imaging-relevant, spatially localized tasks. For example, in some embodiments, the multiphoton excitation pulse 404 can be used to correct the inhomogeneity problems of the on-resonance RF excitation pulse 402. In some embodiments, an optimization framework, for example, known optimization methods, may be used to optimize one or more parameters (e.g., amplitude, phase and frequency of each shim coil current, duration of the low frequency excitation pulse, etc.) of the multiphoton excitation pulse 404 to create a uniform transverse magnetization pattern at the end of the excitation 400. For example, in some embodiments, the optimization of the parameters of the multiphoton excitation pulse 404 may be performed using a target field approach. In some embodiments, gradient field 414 (Gₓ), 416 (G_{y}), and 418 (G_{z}) may also be applied during the multiphoton excitation pulse 404. Gradient fields 414, 416, 418 may be applied using a gradient coils of the MRI system, for example, gradient coil assembly 122 shown in FIG. 1.

While the MP-pTx excitation scheme 400 illustrated in FIG. 4 shows the multiphoton excitation pulse 406 performed after the on-resonance RF excitation pulse 402, in other embodiments, the multiphoton excitation pulse 404 may be applied before an on-resonance excitation pulse 402 or the multiphoton excitation pulse 404 may be used alone. In addition, in some embodiments, multiple combinations of on-resonance RF excitation pulses 402 and multiphoton excitation pulses 404 may be used. If the multiphoton excitation pulse 404 is applied prior to an on-resonance RF excitation pulse 402, the multiphoton excitation pulse 404 can excite spins to preemptively counteract the inhomogeneities that the on-resonance RF excitation pulse 402 may induce. If the multiphoton excitation pulse 404 is applied following the on-resonance RF excitation pulse 402 (as illustrated in FIG. 4), the multiphoton excitation pulse 404 may serve as a “correction” pulse, whereby the multiphoton excitation pulse 404 would attempt to correct, for example, the flip angle inhomogeneities that may be present following the on-resonance RF excitation pulse 402.

In some embodiments, the MP-pTx excitation 400 may include an optional blip period 420. The optional blip period 420 may be applied in a period between the on-resonance RF excitation pulse and before the multiphoton excitation pulse 404. In some embodiments, the blip period 420 can consist of currents 422, 424, 426 applied to the shim (or B_{1z}) coil(s) to impose a spatially-dependent phase on the transverse magnetization. The blip period 420 may also include currents 428, 430, 432 applied to the gradient coils. In some embodiments including a blip period 420, the amplitudes of the currents applied to the shim coils and gradient coils during the blip period 420 may be selected (e.g., optimized and modulated) to create a uniform transverse magnetization pattern at the end of the excitation 400. In some embodiments, if the MP-pTx excitation includes a combination of multiple on-resonance RF excitation pulses 402 and multiple multiphoton excitation pulses 406, a blip period may be applied between each individual pulse.

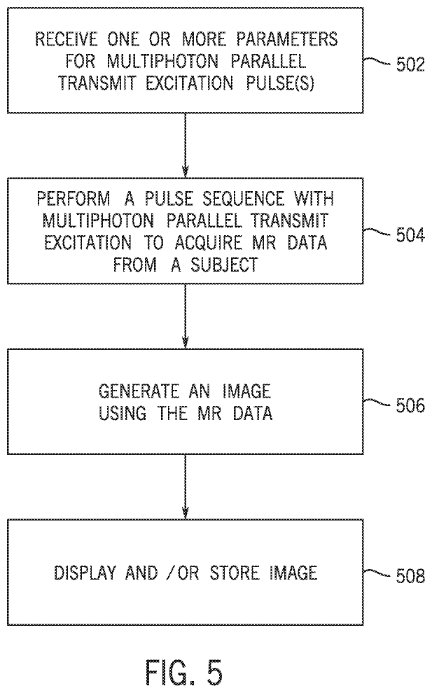

FIG. 5 illustrates a method for generating a magnetic resonance image of a subject using MP-pTx excitation in accordance with an embodiment. Although the blocks of the process in FIG. 5 are illustrated in a particular order, in some embodiments, one or more blocks may be executed in a different order than illustrated in FIG. 3, or may be bypassed.

At block 502, one or more parameters for a multiphoton parallel transmit (MP-pTx) excitation (e.g., MP-pTx excitation 400 shown in FIG. 4) can be received. The MP-pTx excitation can include a multiphoton excitation pulse (e.g., multiphoton excitation pulse 404 in FIG. 4) that, in some embodiments, may be applied before or after an on-resonance RF excitation pulse. The multiphoton excitation pulse can include an off-resonance RF excitation pulse (e.g., off-resonance excitation pulse 406 shown in FIG. 4) and a plurality of low frequency excitation pulses (e.g., low frequency excitation pulses 408, 410, 412 shown in FIG. 4). In some embodiments, the one or more parameters provided at block 502 can include parameters of the multiphoton excitation pulse including parameters of each low frequency excitation pulse (or field), for example, the amplitude, phase, frequency, pulse duration, waveform, etc. of each low frequency excitation pulse. As mentioned above, the one or more parameters may be selected to, for example, optimize the uniformity of the overall excitation or to perform other imaging relevant, spatially localized tasks. In some embodiments, an optimization framework, for example, known optimization methods, may be used to optimize one or more parameters (e.g., amplitude, phase and frequency of each shim coil current, duration of the low frequency excitation pulse, etc.) of the multiphoton excitation pulse to create a uniform transverse magnetization pattern at the end of the MP-pTx excitation. For example, in some embodiments, the optimization of the parameters of the multiphoton excitation pulse may be performed using a target field approach. In some embodiments, the one or more parameters may be provided by a user (or operator), for example, using a user interface or input devices of an MRI system (e.g., MRI system 100 shown in FIG. 1). In some embodiments, the one or more parameters may be retrieved from data storage of an MRI system (e.g., MRI system 100 shown in FIG. 1) or data storage of other computer systems. For example, parameters determined using an optimization method may be stored in data storage and retrieved from data storage for performing the MP-pTx excitation as part of an MR scan of a subject.

At block 504, an MRI system (e.g., MRI system 100 shown in FIG. 1) may be used to perform a pulse sequence with a multiphoton parallel transmit (MP-pTx) excitation to acquire MR data from a subject. The MP-pTx excitation may be utilized during the excitation phase of known pulse sequences for acquired MR data from a subject (e.g., three-dimensional gradient echo (GRE), inversion recovery, spin echo, etc.). As discussed above, the disclosed MP-pTx excitation advantageously includes a multiphoton excitation pulse that, in some embodiments, may be applied before or after an on-resonance RF excitation pulse. The multiphoton excitation pulse can be used to correct spatial inhomogeneities, for example, spatial inhomogeneities of the on-resonance RF excitation pulse, to create a uniform transverse magnetization pattern at the end of the MP-pTx excitation. In some embodiments, the on-resonance RF excitation pulse may be applied using an RF coil (e.g., RF coil 128 or local coil 129) of an MRI system. In some embodiments, the multiphoton excitation pulse can include an off-resonance RF excitation pulse 406 and a plurality of low frequency excitation pulses 408, 410, 412. The off-resonance RF excitation pulse 406 may be applied using an RF coil (e.g., RF coil 128 or local coil 129) of an MRI system. The plurality of low frequency excitation pulses can advantageously be applied using a set of one or more shim coils (e.g., shim coil(s) 250, 302, 304 shown in FIGS. 2, 3A and 3B, respectively).

At block 506, an image of the subject may be generated using the NMR data acquired at block 504. The image of the subject may be reconstructed using known reconstruction methods. At block 510, the generated image of the subject may be stored or displayed. The generated image of the subject may be stored in, for example, data storage of an MRI system (e.g., MRI system 100 shown in FIG. 1) or data storage of other computer systems. The generated image of the subject may be displayed on a display, for example, a display of an MRI system (e.g., displays 104 136 and/or 144 of MRI system 100 shown in FIG. 1) or a display of other computer systems.

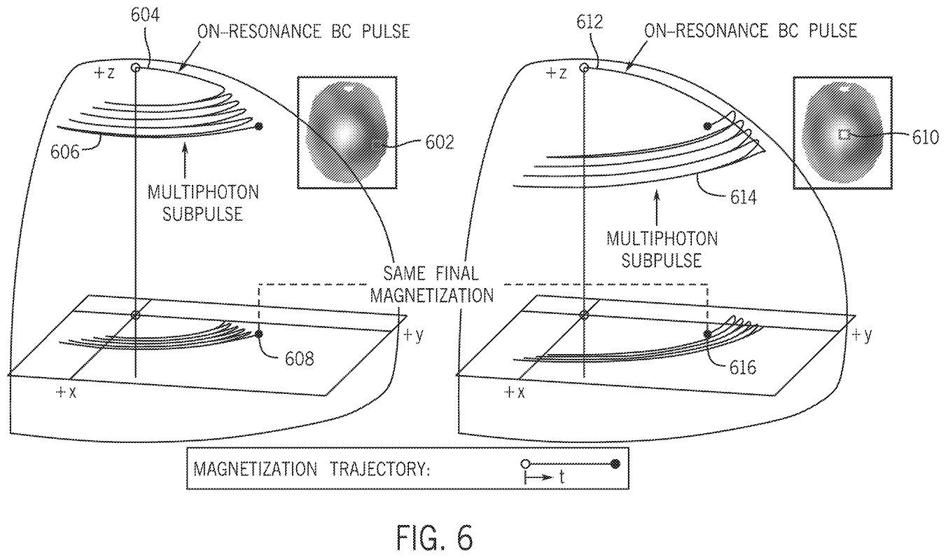

FIG. 6 illustrates example magnetization trajectories for two locations in a subject in accordance with an embodiment. In FIG. 6, example magnetization trajectories for a first location (e.g., a voxel location) 602 marked on a

$${B}_{1}^{+}$$

map within the head and a second location (e.g., a voxel location) 610 marked on a

$${B}_{1}^{+}$$

map within the head are shown. As mentioned above, a MP-pTx excitation (e.g., MP-pTx excitation 400 shown in FIG. 2) can include an on-resonance RF excitation pulse (referred to in FIG. 6 as an On-Resonance Birdcage (BC) Subpulse) and a multiphoton excitation pulse (referred to in FIG. 6 as a Multiphoton Subpulse). The multiphoton excitation pulse can include an off-resonance RF excitation pulse and a plurality of low frequency excitation pulses. In some embodiments, the on-resonance RF excitation pulse can directly and efficiently tip the magnetization towards the y-axis. The on-resonance RF excitation pulse can then be followed by the multiphoton excitation pulse, which can correct the excitation from the inhomogeneous field

$${B}_{1}^{+} ,$$

depending on the relative strength and phase of the B_{1z} field generated by the multiphoton excitation pulse. For the first voxel location 602, the on-resonance RF excitation pulse (e.g., generated by a birdcage coil), under-flips the magnetization 604, and the multiphoton excitation pulse further flips the magnetization 606 toward the xy-plane, bringing the excitation to the correct transverse magnetization (flip angle) 608. For the second voxel location 610 near the center of the head, the on-resonance RF excitation pulse over-flips the magnetization 612, and the multiphoton excitation pulse may be used to generate a magnetization 614 to reduce the flip angle and bring the excitation to the correct magnetization (flip angle) 616.

Computer-executable instructions for multiphoton parallel transmit (MP-pTx) excitation for magnetic resonance imaging according to the above-described methods may be stored on a form of computer readable media. Computer readable media includes volatile and nonvolatile, removable, and non-removable media implemented in any method or technology for storage of information such as computer readable instructions, data structures, program modules or other data. Computer readable media includes, but is not limited to, random access memory (RAM), read-only memory (ROM), electrically erasable programmable ROM (EEPROM), flash memory or other memory technology, compact disk ROM (CD-ROM), digital volatile disks (DVD) or other optical storage, magnetic cassettes, magnetic tape, magnetic disk storage or other magnetic storage devices, or any other medium which can be used to store the desired instructions and which may be accessed by a system (e.g., a computer), including by internet or other computer network form of access.

The present invention has been described in terms of one or more preferred embodiments, and it should be appreciated that many equivalents, alternatives, variations, and modifications, aside from those expressly stated, are possible and within the scope of the invention.

1. A method for generating a magnetic resonance image of a subject using a magnetic resonance imaging (MRI) system, the method comprising:
receiving, using the MRI system, at least one parameter for a multiphoton parallel transmit excitation comprising a multiphoton excitation pulse configured to correct spatial inhomogeneities:
performing, using the MRI system, a pulse sequence comprising the multiphoton parallel transmit excitation to acquire data from the subject, wherein the multiphoton excitation pulse of the multiphoton parallel transmit excitation is performed using a radio frequency (RF) coil and a set of one or more shim coils of the MRI system; and
generating, using a processor, an image of the subject using the acquired MR data.

2. The method according to claim 1, wherein the multiphoton excitation pulse comprises:
an off-resonance RF excitation pulse performed using the RF coil; and
a plurality of low-frequency excitation pulses performed using the set of one or more shim coils, wherein the plurality of low-frequency excitation pulses are performed simultaneously with the off-resonance RF excitation pulse.

3. The method according to claim 2, wherein the off-resonance RF excitation is configured to generate a circularly polarized magnetic field having a frequency offset from a Larmor frequency.

4. The method according to claim 2, wherein the plurality of low frequency excitation pulses are configured to generate a plurality of z-directed oscillating magnetic fields at an offset frequency.

5. The method according to claim 2, wherein the set of one or more shim coils comprises a plurality of shim coils and each shim coil in the plurality of shim coils generates one of the plurality of low frequency excitation pulses.

6. The method according to claim 2, wherein the at least one parameter of the multiphoton parallel transmit excitation comprises an amplitude and phase for each of the plurality of low frequency excitation pulses.

7. The method according to claim 1, wherein the multiphoton parallel transmit excitation further comprises an on-resonance RF excitation pulse before the multiphoton excitation pulse, wherein the on-resonance RF excitation pulse is at the Larmor frequency.

8. The method according to claim 1, wherein the multiphoton parallel transmit excitation further comprises an on-resonance RF excitation pulse after the multiphoton excitation pulse, wherein the on-resonance RF excitation pulse is at the Larmor frequency.

9. The method according to claim 1, wherein the at least one parameter of the multiphoton parallel transmit excitation includes one or more parameters of the multiphoton excitation pulse and the one or more parameters of the multiphoton excitation pulse are configured to optimize the uniformity of the multiphoton parallel transmit excitation.

10. The method according to claim 1, wherein the spatial inhomogeneities are flip angle inhomogeneities.

11. A magnetic resonance imaging (MRI) system comprising:
a magnet system configured to generate a polarizing magnetic field about at least a portion of a subject;
a gradient system including a plurality of gradient coils configured to apply at least one magnetic gradient field to the polarizing magnetic field:
a radio frequency (RF) system including at least one RF coil and configured to apply an RF excitation field to the subject and to receive magnetic resonance signals from the subject using the at least one RF coil:
a set of one or more shim coils; and
a computer system programmed to:
receive at least one parameter for a multiphoton parallel transmit excitation comprising a multiphoton excitation pulse configured to correct spatial inhomogeneities; and
direct the plurality of magnetic gradient coils, the RF coil, and the set of one or more shim coils to perform a pulse sequence comprising the multiphoton parallel transmit excitation to acquire data from the subject, wherein the multiphoton excitation pulse of the multiphoton parallel transmit excitation is performed using the RF coil and the set of one or more shim coils.

12. The MRI system according to claim 11, wherein the computer system is further programmed to generate an image of the subject using the acquired MR data.

13. The MRI system according to claim 11, wherein the multiphoton excitation pulse comprises:
an off-resonance RF excitation pulse performed using the RF coil; and
a plurality of low-frequency excitation pulses performed using the set of one or more shim coils, wherein the plurality of low-frequency excitation pulses are performed simultaneously with the off-resonance RF excitation pulse.

14. The MRI system according to claim 13, wherein the RF coil is a birdcage coil.

15. The MRI system according to claim 13, wherein the set of one or more shim coils comprises a plurality of shim coils and each shim coil in the plurality of shim coils generates one of the plurality of low frequency excitation pulses.

16. The MRI system according to claim 13, wherein the at least one parameter of the multiphoton parallel transmit excitation comprises an amplitude and phase for each of the plurality of low frequency excitation pulses.

17. The MRI system according to claim 11, wherein the multiphoton parallel transmit excitation further comprises an on-resonance RF excitation pulse before the multiphoton excitation pulse, wherein the on-resonance RF excitation pulse is at the Larmor frequency and is performed using the RF coil.

18. The MRI system according to claim 11, wherein the multiphoton parallel transmit excitation further comprises an on-resonance RF excitation pulse after the multiphoton excitation pulse, wherein the on-resonance RF excitation pulse is at the Larmor frequency and is performed using the RF coil.

19. The MRI system according to claim 11, wherein the set of one or more shim coils is positioned in the gradient system.

20. The MRI system according to claim 11, further comprising a local coil, wherein the set of one or more shim coils is positioned in the local coil.
